(19) United States
(12) Patent Application Publication
(10) Pub. No.: US 2018/0286860 A1
(43) Pub. Date: Oct. 4, 2018

(54) CMOS COMPATIBLE LOW GATE CHARGE HIGH VOLTAGE PMOS

(71) Applicant: MAXIM INTEGRATED PRODUCTS, INC., San Jose, CA (US)

(72) Inventors: Frederick Perry Giles, San Jose, CA (US); Stephen McCormack, Mountain View, CA (US); Joel M. McGregor, Nelson (CA)

(21) Appl. No.: 15/938,887

(22) Filed: Mar. 28, 2018

Related U.S. Application Data
(62) Division of application No. 12/618,576, filed on Nov. 13, 2009, now abandoned.

(51) Int. Cl. H01L 27/092; H01L 29/10; H01L 29/06; H01L 29/78

(52) U.S. Cl. CPC H01L 27/092; H01L 29/7816; H01L 29/0653; H01L 29/1045

(57) ABSTRACT

A split gate power transistor includes a laterally configured power PMOSFET including a doped silicon substrate, a gate oxide layer formed on a surface of the substrate, and a split polysilicon layer formed over the gate oxide layer. The polysilicon layer is cut into two electrically isolated portions, a first portion forming a switching gate positioned over a first portion of a channel region of the substrate, and a second portion forming a static gate formed over a second portion of the channel region and a transition region of the substrate. The static plate also extends over a drift region of the substrate, where the drift region is under a field oxide filled trench formed in the substrate. A switching voltage is applied to the switching gate and a constant voltage is applied to the static gate.

### FIELD OF THE INVENTION

The present invention relates to the field of power transistors. More particularly, the present invention relates to the field of integrated MOS power transistors with reduced gate charge.

### BACKGROUND OF THE INVENTION

A power supply is a device or system that supplies electrical or other types of energy to an output load or group of loads. The term power supply can refer to a main power distribution system and other primary or secondary sources of energy. A switched-mode power supply, switching-mode power supply or SMPS, is a power supply that incorporates a switching regulator. While a linear regulator uses a transistor biased in its active region to specify an output voltage, a SMPS actively switches a transistor between full saturation and full cutoff at a high rate. The resulting rectangular waveform is then passed through a low-pass filter, typically an inductor and capacitor (LC) circuit, to achieve an approximated output voltage.

SMPS is currently the dominant form of voltage conversion device because of its high power conversion efficiency, small size and weight, and low cost. SMPS takes input power from a source, such as a battery or wall socket, and converts the input power into short pulses according to the demand for power from the circuits coupled to the SMPS output.

MOSFETs (Metal-Oxide-Semiconductor Field-Effect Transistors) are commonly used in SMPS. MOSFETs are commonly manufactured separately, as discrete transistors. Each MOSFET is then connected to other integrated circuits that are part of the SMPS. Using discrete devices in this manner increases cost and size of the overall SMPS.

High performing MOSFETs are significant to the conversion efficiency of SMPS because MOSFETs are some of the most power dissipating components in the SMPS. Also, the maximum possible switching frequency of the MOSFETs dictates the size, cost, and power losses in the inductors and capacitors included in the SMPS output filter circuits. Under normal SMPS operation, MOSFETs are turned on and off rapidly, so for efficient operation the MOSFETs should have low values of both resistance and gate capacitance.

A MOSFET has a gate, a drain, and a source terminal, as well as a fourth terminal called the body, base, bulk, or substrate. The substrate simply refers to the bulk of the semiconductor in which the gate, source, and drain lie. The fourth terminal functions to bias the transistor into operation. The gate terminal regulates electron flow through a channel region in the substrate, either enabling or blocking electron flow through the channel. Electrons flow through the channel from the source terminal towards the drain terminal when influenced by an applied voltage.

The channel of a MOSFET is doped to produce either an N-type semiconductor or a P-type semiconductor. The drain and source may be doped of opposite type to the channel, in the case of enhancement mode MOSFETs, or doped of similar type to the channel as in depletion mode MOSFETs. The MOSFET utilizes an insulator, such as silicon dioxide, between the gate and the substrate. This insulator is commonly referred to as the gate oxide. As such, the gate terminal is separated from the channel in the substrate by the gate oxide.

When a voltage is applied between the gate and source terminals, the electric field generated penetrates through the gate oxide and creates a so-called “inversion layer”, or channel, at the semiconductor-insulator interface. The inversion channel is of the same type, P-type or N-type, as the source and drain, so as to provide a channel through which current can pass. Varying the voltage between the gate and substrate modulates the conductivity of this layer, which functions to control the current flow between drain and source.

A power MOSFET is a specific type of MOSFET widely used as a low-voltage switch, for example less than 200V. A lateral power MOSFET refers to a configuration where both the drain and the source are positioned lateral of each other, such as both at the top surface of the substrate. This is in contrast to a vertical power MOSFET where the drain and source are stacked vertically relative to each other, such as the source at the top surface of the substrate and the drain at the bottom surface.

One limiting factor in how fast the power MOSFET can be switched on and off is the amount of gate charge needed to turn the transistor on and off. The gate charge refers to the number of electrons that are moved into and out of the gate to turn the transistor on and off, respectively. The larger the needed gate charge, the more time to switch the transistor on and off. There is an advantage to quickly switching the power transistor in a switch-mode power supply. The higher the frequency, the smaller the size of the discrete components used in the gate drive circuit of the SMPS. Smaller components are less expensive than larger components.

FIG. 1 illustrates a cut-out side view of an exemplary configuration of a conventional lateral power P-channel MOSFET. In this exemplary configuration, the substrate 10 is doped to form a N-type region, or well, 12 and a P-type region, or well, 14. The N-type well 12 includes a double diffused source 16 having a merged contact 24 between a N+ region 20 and a P+ region 22. The contact 24 shorts the N+ region 20 and the P+ region 22 together. The contact 24 functions as a source contact of the power transistor, and the source is shorted to the body of the substrate, which is N-type in this exemplary configuration. A source contact terminal 42 is coupled to the contact 24, and therefore to the source 16. The substrate 10 is also doped to form a P+ region 18 within the P-type region 14. The P+ region 18 functions as the drain of the power transistor. A drain contact terminal 40 is coupled to the drain 18. A trench 26 is formed in a top surface of the substrate 10. The trench 26 is filled with field oxide. The trench 26 can be formed using Shallow Trench Isolation (STI) and in this case the field oxide filled trench is referred to as a shallow trench isolation (STI) region.

A gate oxide 28 is formed on the top surface of the substrate 10. A polysilicon gate 30 is formed over the gate oxide 28. As shown in FIG. 1, the gate oxide layer 28 between the polysilicon gate 30 and the substrate 10 is a thin oxide layer. The polysilicon gate 30 extends over the STI region to support high drain-to-gate voltage.

There are three main regions in the substrate 10 relative to the operation of the power transistor: a channel region, a transition region, and a drift region. The channel region is formed underneath the polysilicon gate 30 and in the N-type region 12 of the substrate 10. In other words, the channel region is formed where the polysilicon gate 30 overlaps the N-type region 12. The drift region is the portion of the P-type region 14 underneath the trench 26, or the STI region. The drift region is where most of the drain-to-gate voltage is dropped in the transistor off state. The STI region is necessary to achieve a high drain-to-gate voltage. If the polysilicon gate 30 were to instead terminate over the thin gate oxide, this would result in too high a voltage across the gate oxide and the power transistor would not function. As such, the STI region and the polysilicon gate extension over the STI region are necessary to drop the high gate-to-drain voltage.

The transition region is the portion of the P-type region 14 underneath the gate oxide 28 and the polysilicon gate 30. The transition region provides a current flow path from the channel region to the drift region when the power transistor is turned on. The transition region is also referred to as the accumulation region or the neck region. In many applications, the transition region accounts for the largest single component of on-resistance in a low-voltage power MOSFET. An on-resistance of the power MOSFET is the resistance between the drain and the source while the transistor is turned on. The length of the transition region is an important design consideration, where the length refers to the horizontal direction in FIG. 1. If the length is too short, the on-resistance of the power MOSFET increases, and the device suffers from early quasi-saturation when turned on hard. If the length is too long, the on-resistance saturates, the specific on-resistance increases, and the breakdown voltage drops. The portion of the polysilicon gate 30 positioned over the transition region accounts for a significant portion of the gate capacitance, and therefore the gate charge.

### SUMMARY OF THE INVENTION

A split gate power transistor includes a laterally configured power P-channel MOSFET having a doped silicon substrate, a gate oxide layer formed on a surface of the substrate, and a split polysilicon layer formed over the gate oxide layer. The polysilicon layer is cut into two electrically isolated portions, a first portion forming a polysilicon switching gate positioned over a first channel region of the substrate, and a second portion forming a polysilicon static gate formed over a second channel region and a transition region of the substrate. The first channel region and the second channel region are bridged by a doped bridge region in the substrate. A portion of the static gate extends over a drift region of the substrate, where the drift region is under a field oxide filled trench formed in the substrate. The extended portion of the static gate functions as a field plate to establish a high breakdown voltage. The switching gate is electrically coupled to a first voltage source and the static gate is electrically coupled to a second voltage source.

In an aspect, a split gate power transistor is disclosed. The split gate power transistor includes: a doped substrate comprising a P-type source, a P-type bridge, a first N-type channel region, and a second N-type channel region within a doped N-type region, a P-type drain and a P-type transition region within a doped P-type region, and a trench within the doped P-type region, wherein the trench is formed in a first surface of the substrate and the trench is filled with field oxide, further wherein the first channel region is positioned between the source and the bridge, the second channel region is positioned between the bridge and the transition region, the transition region is positioned between the second channel region and the trench, and the trench is positioned between the transition region and the drain; a gate oxide layer positioned on the first surface of the substrate; a first gate positioned on the gate oxide layer and over the first channel region; and a second. gate positioned on the gate oxide layer and over the second channel region, the transition region, and a portion of the trench, wherein the first gate is separated from the second gate such that at least a portion of the bridge is uncovered by both the first gate and the second gate.

In another aspect, a method of fabricating a split gate power transistor is disclosed. The method includes: doping a substrate to form a P-type source and a N-type channel region within a doped N-type region, and a P-type drain and a P-type transition region within a doped P-type region, wherein the channel region is positioned between the source and the transition region, and the transition region is positioned between the channel region and the drain; forming a trench within a portion of the P-type region proximate the drain; filling the trench with a field oxide; applying a gate oxide layer to a top surface of the substrate; forming a conductive layer over the channel region, the transition region, and a portion of the trench; removing a portion of the conductive layer over a first portion of the channel region, thereby forming two separate conductive layer portions including a first conductive layer portion positioned over a first portion of the channel region, and a second conductive layer portion positioned over a second portion of the channel region, the transition region, and the portion of the trench; and doping the first conductive layer portion, the second conductive layer portion, and a third portion of the channel region exposed where the portion of the conductive layer is removed, thereby forming a doped P-type bridge region between the first portion of the channel region and the second portion of the channel region. In some embodiments, the doped N-type region includes a first N-type well and a second N-type well doped within the first N-type well. The method also include forming a first conductive channel in the first portion of the channel region between the source and the doped bridge region, and forming a second conductive channel in the second portion of the channel region between the doped bridge region and the transition region. The first conductive channel is formed by applying a first voltage to the first gate, and the second conductive channel is formed by applying a second voltage to the second gate. In some embodiments, the power transistor is fabricated using processes compatible with fabricating a complimentary metal-oxide-semiconductor device. In some embodiments, the power transistor is fabricated monolithically as an integrated circuit that includes a switch mode power supply circuit.

The first gate and the second gate are electrically isolated from each other. The first gate is electrically coupled to a first voltage supply, and the second gate is electrically coupled to a second voltage supply. In some embodiments, a constant voltage is applied to the second gate and a switching voltage is applied to the first gate. In other embodiments, a constant voltage is applied to the first gate and a switching voltage is applied to the second gate. In some embodiments, the gate and the field plate are polysilicon. In some embodiments, the doped substrate also includes a P-type substrate and a N-type epitaxial layer, wherein the doped N-type region and the doped P-type region are formed in the N-type epitaxial region. In this configuration, when the power transistor is turned on, a current flow from the transition region to the drain is restricted to the doped P-type region. In some embodiments, the doped substrate also includes a P-type isolation ring within which the N-type epitaxial layer forms a N-type epitaxial pocket. In some embodiments, the power transistor comprises a lateral double-diffused P-channel metal-oxide-semiconductor field-effect transistor. The doped substrate also includes a drift region within the doped P-type region, wherein the drift region is positioned under the trench between the transition region and the drain. In some embodiments, the substrate comprises a silicon substrate. In some embodiments, the source comprises a double-diffused region. In some embodiments, the trench is formed using a shallow trench isolation process.

### BRIEF DESCRIPTION OF THE DRAWINGS

FIG. 1 illustrates a cut-out side view of an exemplary configuration of a conventional lateral power PMOSFET.

FIG. 2 illustrates a cut-out side view of a split gate laterally-configured power transistor according to a first embodiment.

FIG. 3 illustrates a cut-out side view of a split gate laterally-configured power transistor according to a second embodiment.

FIG. 4 illustrates a schematic diagram of an exemplary power converter according to a first embodiment.

FIG. 5 illustrates a schematic diagram of an exemplary power converter according to a second embodiment.

FIG. 6 illustrates a schematic diagram of an exemplary power converter according to a first embodiment.

FIG. 7 illustrates a gate charge curve for a conventional power MOSFET, such as that shown in FIG. 1, and the split gate power MOSFET, such as that of FIG. 2.

Embodiments of the split gate power transistor are described relative to the several views of the drawings. Where appropriate and only where identical elements are disclosed and shown in more than one drawing, the same reference numeral will be used to represent such identical elements.

### DETAILED DESCRIPTION OF THE EMBODIMENTS:

Embodiments of the present application are directed to a split gate power transistor. Those of ordinary skill in the art will realize that the following detailed description of the split gate power transistor is illustrative only and is not intended to be in any way limiting. Other embodiments of the split gate power transistor will readily suggest themselves to such skilled persons having the benefit of this disclosure.

Reference will now be made in detail to implementations of the split gate power transistor as illustrated in the accompanying drawings. The same reference indicators will be used throughout the drawings and the following detailed description to refer to the same or like parts. In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application and business related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

Embodiments of a split gate power transistor include a laterally configured power PMOSFET having a doped silicon substrate, a gate oxide layer formed on a surface of the substrate, and a split polysilicon layer formed over the gate oxide layer. The polysilicon layer is cut into two electrically isolated portions, a first portion forming a polysilicon switching gate positioned over a first channel region of the substrate, and a second portion forming a polysilicon static gate formed over a second channel region and a transition region of the substrate. The first channel region and the second channel region are bridged by a doped bridge region in the substrate. The bridge is doped the same type as the source and the drain. A portion of the static gate extends over a drift region of the substrate, where the drift region is under a field oxide filled trench formed in the substrate. The extended portion of the static gate functions as a field plate to establish a high breakdown voltage. The switching gate is electrically coupled to a first voltage source and the static gate is electrically coupled to a second voltage source. In an exemplary application, a constant voltage is applied to the static gate, and a high frequency switching voltage is applied to the switching gate. The constant voltage applied to the static gate is large enough to establish an inversion layer in the second channel region below the static gate. With the constant voltage applied, the static gate functions as the field plate.

The polysilicon layer is cut over a channel region, or body, of the PMOSFET. The substrate includes a doped bridge region, referred to as a bridge, that splits the channel region to form the first channel region and the second channel region. The bridge is formed during fabrication of the switching gate and the static gate. When the polysilicon layer is cut, a portion of the substrate is exposed where the cut portion of the polysilicon is removed. The two polysilicon portions and the exposed portion of substrate are doped. During this doping process, the doped bridge region is formed at the exposed portion of the substrate. The bridge splits the would be channel region into the first channel region and the second channel region. The first channel region is positioned between the source and the bridge. The second channel region is positioned between the bridge and the transition region.

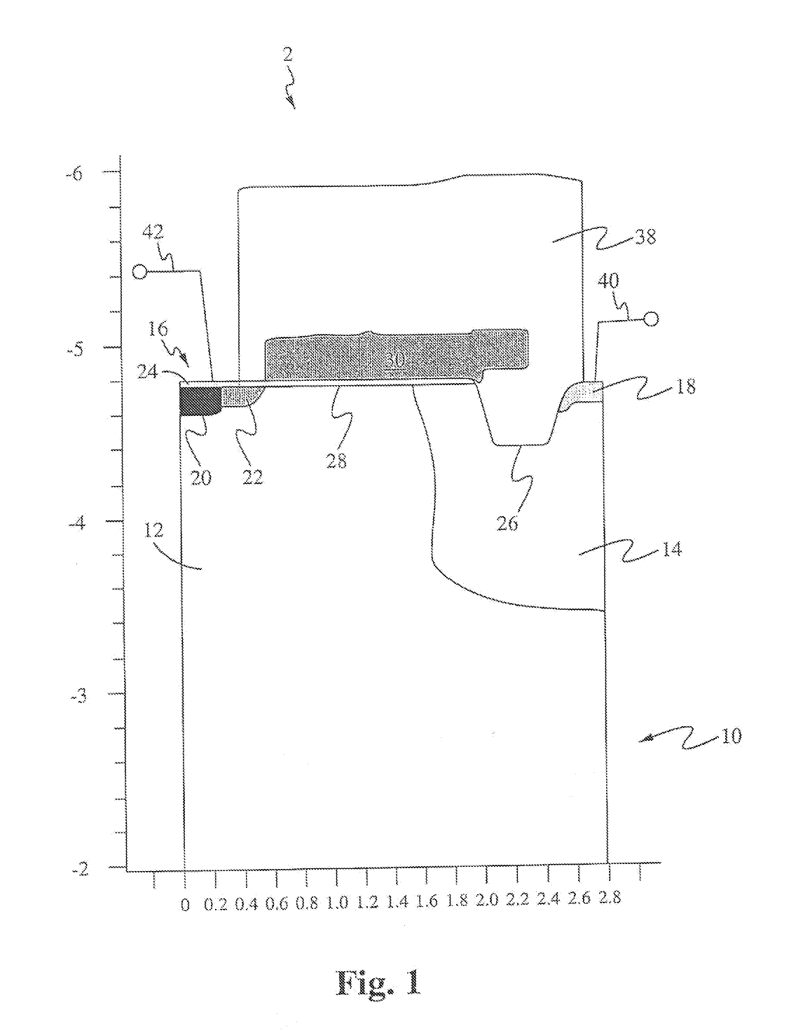

In conventional power MOSFETs, such as that shown in FIG. 1, a significant component of the gate capacitance is due to the gate-to-drain capacitance at the transition region. Applying a switching voltage to the gate amplifies the gate-to-drain capacitance due to the Miller effect. In the split gate power transistor, the switching portion of the gate, the switching gate, is isolated to the channel region, while the portion of the gate over the transition region, the static gate, remains at a constant voltage. This reduces, if not eliminates, the Miller capacitance between the gate and the drain. Also, by reducing the area of the switching gate, the amount of charge, the gate charge, transferred during each switching cycle is reduced. The gate charge determines how fast a switch is turned on and off. Reducing the gate charge allows for higher-frequency switching operation. The higher frequency allows for the use of smaller discrete components which reduces costs. Additionally, the split gate power transistor has a lower on-resistance than a comparable single gate power transistor. This is due to the addition of the doped bridge region into the channel region. The doped bridge region is more conductive than an inverted channel region. In this manner, the split gate power transistor configuration conceptually shortens the length of the “channel region” by adding the doped bridge region.

The split gate power transistor configuration is applicable to all switchable power supply integrated circuits that have internal switches. The fabrication process for the split gate power transistor is CMOS compatible As such, the split gate power transistor can be manufactured monolithically with the output circuit of the SMPS circuit. This configuration is not limited to integrated MOSFETs. The split gate power transistor configuration can be applied to any lateral power MOSFET, either integrated or discrete.

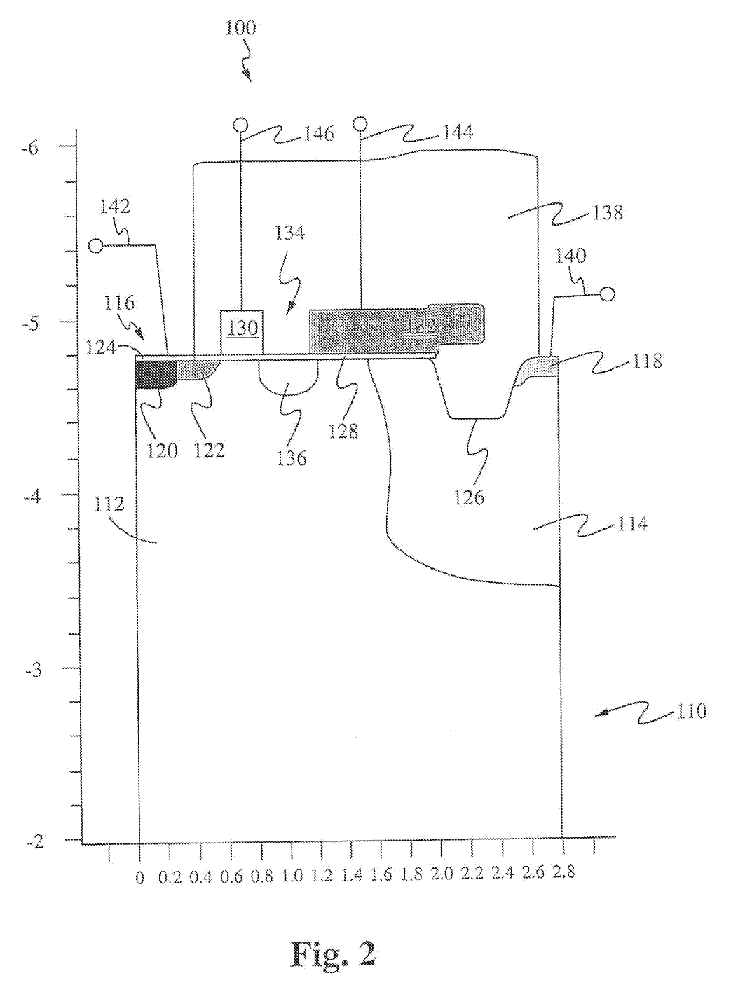

FIG. 2 illustrates a cut-out side view of a split gate laterally-configured power transistor 100 according to a first embodiment. In this exemplary configuration, the power transistor 100 is a P-channel double-diffused MOSFET (P-channel DMOSFET). The substrate 110 is doped to form a N-type region112 and a P-type region 114. The N-type region 112 includes a double-diffused source 116 having a merged contact 124 between a N+ region 120 and a P+ region 122. The contact 124 shorts the N+ region 120 and the P+ region 122 together. The contact 124 functions as a source contact of the split gate power transistor, and the source is shorted to the body of the substrate, which is N-type. The N-type region 112 extends across the entire width of the lower portion of the substrate 110, including underneath the P-type region 114 on the right hand side of FIG. 2. A source contact terminal 142 is coupled to the contact 124, and therefore to the source 116. The substrate 110 is also doped to form a P+ region 118 within the P-type region 114. The P+ region 118 functions as the drain of the split gate power transistor. A gate contact terminal 140 is coupled to the drain 118. A trench 126 is formed in a top surface of the substrate 110. The trench 126 is filled with field oxide. In some embodiments, the trench 126 is formed using a Shallow Trench Isolation (STI) process, and the field oxide filled trench is referred to as a STI region. In other embodiments, the trench 126 is formed using any conventional semiconductor fabrication technique capable of removing a portion of the substrate used to form a thick field oxide region.

A gate oxide 128 is formed on the top surface of the substrate 110. In some embodiments, the gate oxide layer is deposited using conventional semiconductor deposition processes. A polysilicon layer is formed over the gate oxide 128. A slice of the polysilicon layer is removed, forming two electrically isolated polysilicon portions. The slice of the polysilicon layer is removed from above the N-type region 112. In some embodiments, the polysilicon portions are formed using conventional semiconductor deposition and etching processes. A first polysilicon portion forms a switching gate 130. A second polysilicon portion forms a static gate 132. The switching gate 130 and the static gate 132 are physically separated by a gap 134, which corresponds to the removed slice of polysilicon. A doped bridge region 136, referred to as a bridge, is formed in the substrate below the gap 134. The bridge 136 is formed during fabrication of the switching gate 130 and the static gate 132. Fabricating the switching gate 130 and the static gate 132 includes a doping step. During this doping step, a mask is applied that leaves the switching gate 130, the static gate 132, and the portion of substrate under the gap 134 exposed to dopant. As the dopant is applied, the doped bridge region 136 is formed at the exposed portion of the substrate. The switching gate 130, the static gate 132, and the bridge 136 are doped the same type as the source region 122, and the drain 118, which in this case is P-type.

An insulating oxide 138 covers the switching gate 130 and the static gate 132. As shown in FIG. 2, the gate oxide layer 128 between the switching gate 130 and the substrate 110, and the gate oxide layer 128 between the static gate 132 and the substrate 110 is a thin oxide layer. In some embodiments, the gate oxide layer underneath the switching gate 130 has a same thickness as the gate oxide layer underneath the static gate 132. The static gate 132 is electrically isolated from the switching gate 130 by the gap 134. In many applications, power transistors are laid out having many interdigitated stripes, for example a source stripe, a gate stripe, and a drain stripe. For example, the drain stripe functions as the drain contact terminal 140, and the source.stripe functions as the source contact terminal 142. In the split gate power transistor, the switching gate and the static gate can also be laid out in stripes, separated by the gap. For example, the static gate stripe functions as a static gate contact terminal, schematically illustrated in FIG. 2 as static gate contact terminal 144, and the switching gate stripe functions as a switching gate contact terminal, schematically illustrated in FIG. 2 as switching gate contact terminal 146. In reference to FIG. 2, the stripes are oriented into and out of the plane of the page. If a gate is normally connected at the end of its stripe, which can be hundreds of microns long, the switching gate and the static gate can similarly extend as stripes, the ends of which can be electrically connected to a first voltage supply and a second voltage supply, respectively. Alternatively, the source, drain, switching gate, and/or static gate can be configured for electrical coupling along an entire width of the device, or along periodic contact points along the device width, where the width of the device is into and out of the page of FIG. 2. In these alternative configurations, one or more gaps can be cut into the oxide 138 to provide contact access points to the switching gate 130 and to the static gate 132. A gap is cut in the oxide 138 at each desired contact point or region.

The static gate 132 extends over the field oxide filled trench 126 to support high gate-to-drain voltage. The static gate 132 is necessary to maintain a higher breakdown voltage. If the static gate is not extended over the trench 126, or the trench 126 itself is removed, the breakdown voltage suffers. In this case, almost all the gate-to-drain voltage is dropped across the thin gate oxide, which does not enable the power transistor to meet the rated voltage.

There are four main regions in the substrate 110 relative to the operation of the split gate power transistor: a first channel region, a second channel region, a transition region, and a drift region. The first channel region is formed underneath the switching gate 130 and in the N-type region 112 of the substrate 110. The second channel region is formed underneath the static gate 132 and in the N-type region 112 of the substrate 110. In other words, the second channel region is formed where the static gate 130 overlaps the N-type region 112. The bridge 136 splits what would have been a single channel region in the N-type region 112 if the gap 134 had not been formed. In the split gate power transistor, the bridge 136 splits this would be single channel region into two separately controllable channel regions, the first channel region and the second channel region. The first channel region is positioned between the source region 122 and the bridge 136. The second channel region is positioned between the bridge 136 and the transition region within the P-type region 114. The transition region is the portion of the P-type region 114 underneath the static gate 132. The transition region is also referred to as the accumulation region or the neck region. The position of the bridge 136, and therefore the gap 134, is far enough from the source region 122 so as to prevent punch-through from the source122 to the bridge 136 when the device is in an off state. The bridge 136 is also positioned far enough from the P-N junction between the second channel region and the transition region so as to not negatively impact the breakdown voltage.

The drift region is the portion of the P-type region 114 underneath the trench 126, or the STI region. The drift region is necessary to support a high gate-to-drain voltage. If the static gate 132 were to instead terminate over the thin gate oxide, this would result in too high a voltage over the gate oxide and the split gate power transistor would not function. As such, the STI region and the static gate extension over the STI region are necessary to drop the high gate-to-drain voltage.

Compared to a comparable conventional single gate power transistor that does not have a split gate configuration, such as the power transistor 100 in FIG. 1, the first channel region, the second channel region, and the bridge of the power transistor 200 have the same combined length as channel region of the single gate power transistor. In this regard, the power transistor 200 does not suffer from an increase in area to accommodate the doped bridge region. Further, the doped P-type bridge region 136 is more conductive than if the same area were an inverted channel, as in the power transistor 100 (FIG. 1). As such, the carrier mobility in the P-type bridge region is improved, thereby reducing the on-resistance compared to a comparable single gate power transistor.

In operation, a first voltage supply is electrically coupled to the switching gate 130, schematically shown as terminal 146 in FIG. 2, and a second voltage supply is electrically coupled to the static gate 132, schematically shown as terminal 144 in FIG. 2. A constant voltage is applied to the static gate 132, thereby creating a conductive channel in the second channel region between the bridge 136 and the transition region. With the constant voltage applied, the portion of the static gate 132 that extends over the trench 126 also functions as a field plate. In an exemplary application, the constant voltage is -5V. In. general, the constant voltage is large enough to create the conductive channel, but not large enough to rupture the gate oxide between the static gate 132 and the substrate 110. The constant voltage applied to the static gate 132 is the gate-to-drain voltage Vgd. A switching voltage is applied to the switching gate 130. The switching voltage alternates between a low, turn-on voltage and a high, turn-off voltage according to the switching frequency of the device. In an exemplary application, the turn-off voltage is 0V and the turn-on voltage is −5V. The switching voltage applied to the switching gate 132 is the gate-to-source voltage Vgs.

When the switching voltage is high, a conductive channel is created between the source P+ region 122 and the P-type bridge 136, thereby turning-on the transistor. With the transistor turned on, current flows from the source 116 through the first channel formed underneath the switching gate 130 to the bridge 136, through the second channel formed underneath the static gate 132 to the transition region, and through the transition region and drift region to the drain 118. The transition region and the drift region provide a current flow path from the second channel region to the drain 118 when the split gate power transistor is turned-on. When the switching voltage is low, the current can not flow from the P+ region 122 to the bridge 136 since the conductive channel in the first channel region is not created, thereby turning-off the transistor.

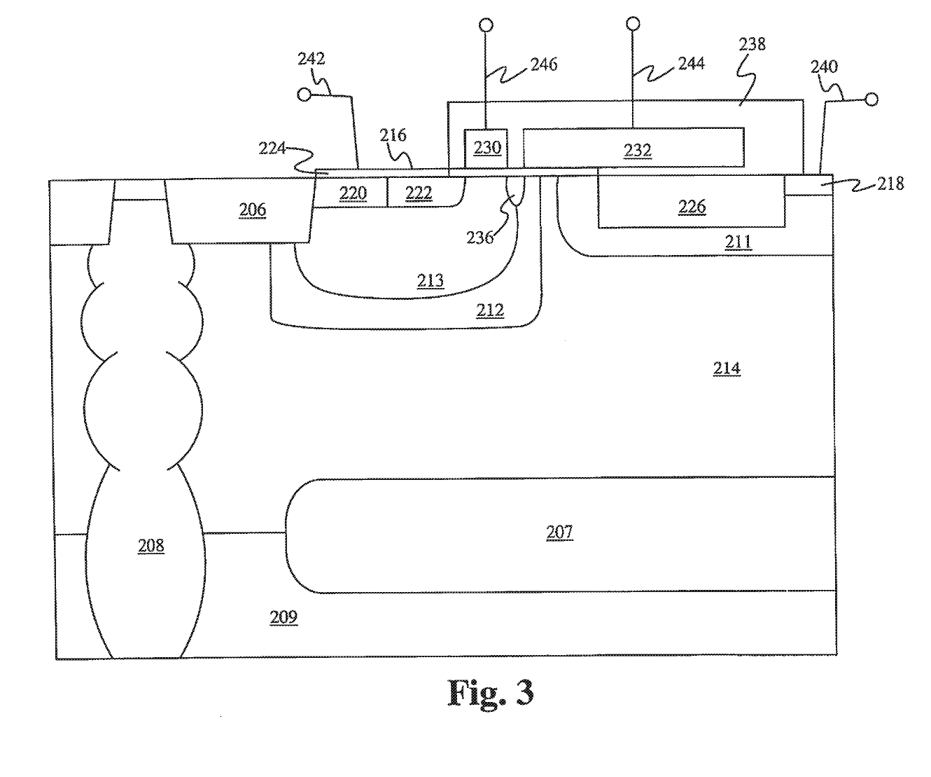

FIG. 3 illustrates a cut-out side view of a split gate laterally-configured power transistor 200 according to a second embodiment. The power transistor 200 is configured similarly as the power transistor 100 of FIG. 2 except that the substrate is doped differently. The power transistor 200 includes a P-type substrate 209, a N-type buried layer (NBL) 207, a N-type epitaxial layer 214, a N-type region 212, a N-type region 213, a P-type region 211, and a P-type isolation ring 208. The N-type region 212 forms a first N-type well with the N-type epitaxial layer 214, and the N-type region 213 forms a second N-type well within the first N-type well 213. The N-type region 213 has a higher N-type concentration than the N-type region 212, and the N-type region 212 has a higher N-type concentration than the N-type epitaxial layer 214. The N-type region 213 includes a P+ bridge region 236 and a double-diffused source having a merged contact between a N+ region 220 and a P+ region 222. The two N-type wells 212 and 213 together form the channel doping, or body. Both the N-type region 212 and the N-type region 213 contribute to the surface concentration that determined the threshold voltage of the device. The doping concentrations used for the two N-type regions 212 and 213 are determined according to the designed threshold voltage. In some embodiments, the first channel region is formed in the N-type region 213, and the second channel region is formed in the N-type region 212 and the N-type epitaxial region 214. In operation, first and second conductive channels are formed in a manner similar to the power transistor 100 of FIG. 2.

The P-type region 211 forms a P-type well within which the P+type drain 218 and the oxide-filled trench 226 is formed. The P-type region 211 has a lower P-type concentration than the P+type drain 218. The P-type region 211 is also referred to as a low energy P-well (LEPW). The N-type epitaxial layer 214 extends underneath both the P-type region 211 and the N-type region 212. The NBL 207 has a relatively higher N-type concentration than the N-type region 214. The P-type region 211 forms the drift region underneath the trench 226. Current flowing through the second channel region flows through the transition region and the drift region to the drain 218. There is no current flow through the N-type epitaxial layer 214 other than through the inversion layer generated in that portion of the N-type epitaxial layer 214 that forms the second channel region. Minimizing the thickness of the P-type region 211 reduced the on-resistance. Providing a doped P-type well 211 within the N-type epitaxial layer 214 enables a manner of lowering the on-resistance without effecting the rest of the transistor.

The P-type isolation ring 208 forms a perimeter within the substrate of the split gate power transistor 200. Only a portion of the P-type isolation ring is shown in FIG. 3. The N-type epitaxial layer 214 is isolated inside the perimeter formed by the P-type isolation ring 208, thereby forming a N-type epitaxial pocket. In this manner, other circuits monolithically formed with the power transistor 200, if applicable, are isolated from the power transistor 200, and are specifically isolated from the N-type epitaxial layer 214. The oxide-filled trench 206 separates the source well from the P-type isolation ring.

FIG. 7 illustrates a gate charge curve for a conventional power MOSFET, such as that shown in FIG. 1, and the split gate power MOSFET, such as that of FIG. 2. The gate charge curve is a common figure of merit for MOSFETs. To determine the gate charge, the drain is connected to a nominal supply voltage through a load resistance, the source is grounded, and the gate is grounded. A constant current is forced into the gate, and the gate-to-source voltage Vgs is measured. As the supply voltage is applied to the gate, the gate-to-source voltage Vgs starts to rise until the threshold voltage is reached, which is −1.5V in this example. The threshold voltage corresponds to the flat portion of the curve, which is where the power transistor begins to turn on. When the gate-to-source voltage Vgs reaches the fully rated voltage, which is -5V in this example, the trace is stopped. The gate charge is determined as the integration of the measured voltage. In the example shown in FIG. 7, the gate charge curves are measured for power MOSFETS having a rated gain-to-source voltage of −5V and an operating voltage of 24V.

The curve 600 is the gate charge curve of the split gate power transistor of FIG. 2, and the curve 610 is for a similar conventional power transistor, such as the power transistor of FIG. 1. It is seen in FIG. 7 that the gate charge of the split gate power transistor is reduced compared to the conventional power transistor. Reducing the size of the active gate, by removing the slice of polysilicon, reduces the gate charge. It is still necessary to prevent the breakdown of the split gate power transistor, which is accomplished using the field plate. The active polysilicon gate and the field plate are electrically isolated so that the charge that effects the active gate is reduced to the lowest possible level.

It can also be seen that the flat portion of the curve 600 is reduced compared to the flat portion of the curve 610. The flat portion represents the gate-to-drain charge Qgd, which is the integral of the gate-to-drain voltage across the flat region. Within the flat region, more and more current is forced into the gate, but the gate-to-source voltage remains constant.

The gate-to-drain charge Qgd is related to the feedback capacitance between the drain and the gate. In general, the portion of the gate that is positioned over the drain well is amplified and has more of an effect on the gate charge than the portion of the gate that is over the source well. By splitting the polysilicon gate into the switching gate and the static gate, and applying a constant voltage to the static gate, which is the only gate portion positioned over the drain well, the feedback capacitance related to the Miller effect is reduced if not eliminated.

The split gate power transistor provides a reduction in the product of on-resistance (R) and gate charge (Qg), due both to the reduction in gate charge Qg and the reduction in on-resistance, as previously described. The split gate power transistor also results in a reduction in the specific on-resistance, which is the product of on-resistance (R) and gate area (A). The specific on-resistance provides a conceptual measure of the size of the power transistor. The specific on-resistance of the split gate configuration decreases compared to a comparable conventional power transistor that does not have a split gate configuration, such as the power transistor 2 in FIG. 1, because the gate area A is reduced by removing the slice of polysilicon. The specific on-resistance is also decreased because the on-resistance R is reduced due to the improved conductivity of the channel region at the doped bridge region. The doped P-type bridge region 136, 236 is more conductive than if the same area were an inverted channel, as in the power transistor 2 (FIG. 1). As such, the carrier mobility in the P-type bridge region 136, 236 is improved, thereby reducing the on-resistance and the specific on-resistance.

When the split gate power transistor is turned completely on, for example when the constant voltage applied to the static gate is −5V and the switching voltage applied to the switching gate is high, the current flows through the first channel region, the bridge, and the second channel region, through the transistor region and the drift region, which is under the field oxide filled trench, and back up to the P+ drain. Due to the constant voltage at the static gate, which covers the transition region, electrons accumulate in the transition region.

In an exemplary application, accounting for all effects related to the split gate configuration with a threshold voltage of −5V there is an approximate 73% decrease in gate charge Qg, an approximate 77% reduction in the R*Qg product, an approximate 15% decrease in the R*A product, and an approximate 1.6V increase in the breakdown voltage BVdss compared to comparable single gate power transistor that does not have the split gate configuration. The portion of the static gate extending over the trench functions as a field plate. In general, a field plate reduces the electric field for any given supply voltage, which effectively maintains or increases the breakdown voltage of the split gate power transistor.

In an exemplary application, the cut gap between the switching gate and the static gate is fabricated using 0.18 micron semiconductor processing technology, resulting in a 0.25 micron wide gap. However, the gap can be larger or smaller than 0.25 microns, limited in size only by the available technology. For example, utilization of 0.13 micron semiconductor fabrication technology can achieve a gap width of 0.2 microns. In practice, the gap can be as small as technology allows.

The following highlight some of the properties of the split gate power transistor, especially as compared to a comparable single gate power transistor. First, the gate capacitance and the gate charge are reduced because the switching portion of the gate, the switching gate, has a smaller gate area. Second, because a constant voltage is applied to the static gate that is over the transition region, the gate-to-drain feedback capacitance is greatly reduced. This further reduces the gate charge compared to a comparable single gate power transistor because during switching, the gate-to-drain capacitance is amplified by the Miller effect. Third, the breakdown voltage BVdss is increased. Fourth, switch mode power supply (SMPS) efficiency is improved. Fifth, the process of fabricating the split gate power transistor is CMOS compatible. As such, the split gate power transistor can be fabricated monolithically with CMOS devices, including the driver circuits of a SMPS. Fabrication of a power MOSFET on the same integrated circuit as the SMPS circuit results in smaller overall SMPS system size and cost.

In general, the switching gate and the static gate can be depletion-mode MOS devices or enhancement-mode MOS devices. The bridge is required for the device to operate properly if the static gate is operated in enhancement mode.

The gate material is described above as being polysilicon. Alternatively, the gate can be made of any conventional material used in the fabrication of semiconductor transistors including, but not limited to, polysilicon and/or metal. The substrate is described above as being silicon. Alternatively, the substrate can be a silicon-based compound, for example silicon germanium (SiGe).

The operation of the split gate power transistor is described above as applying a switching voltage to the gate 130, 230 and a static voltage to the gate 132, 232. Alternatively, the split gate power transistor can be operated such that a constant voltage is applied to the gate 130, 230 and a switching voltage is applied to the gate 132, 232. In an exemplary application, this alternatively configured power transistor functions as an integrated high voltage NAND gate. This integrated device reduces total device area compared to a conventional low-side switching device that connects a discrete CMOS device to a lateral DMOS.

In another exemplary application, the PMOSFET is coupled with a NMOSFET within a power converter. More specifically, the power converter includes a PMOSFET, a NMOSFET, and a load, where the PMOSFET is coupled to the high-side of the load and the NMOSFET is coupled to the low-side. Such a configuration is commonly found in a buck-type power converter, amongst others. The PMOSFET can be implemented using the split gate PMOSFET described herein, and the NMOSFET can be implemented using a split gate NMOSFET such as the type described in the co-owned U.S. Patent Application Serial No. (MAXIM-03100) or the co-owned U.S. Patent Application Serial No. (MAXIM-03200). U.S. Patent Application Serial No. (MAXIM-03100) and U.S. Patent Application Serial No. (MAXIM-03200) are hereby incorporated in their entireties by reference.

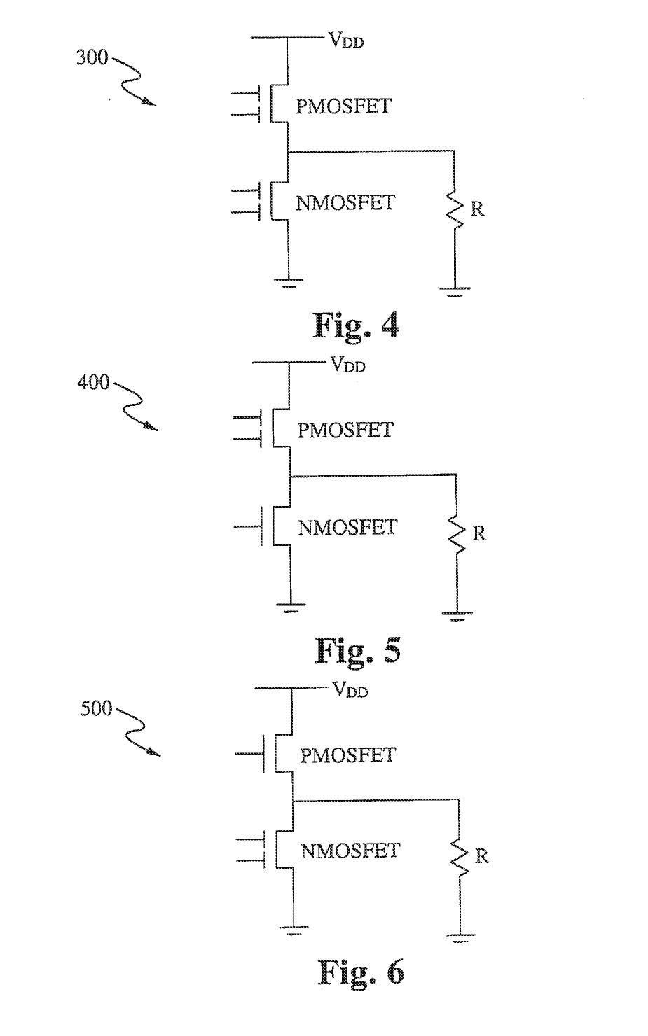

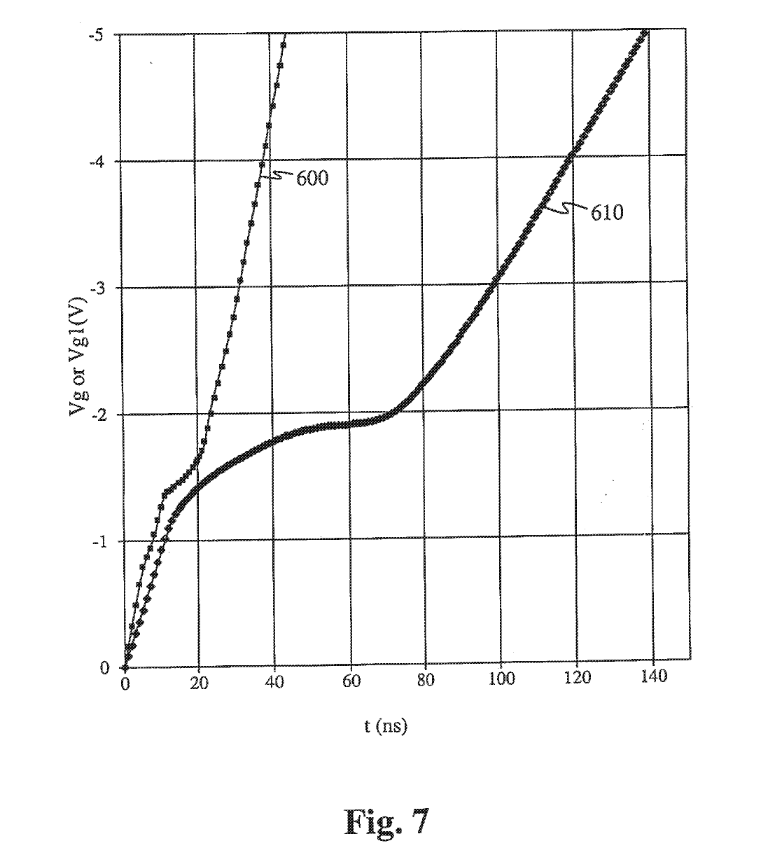

FIG. 4 illustrates a schematic diagram of an exemplary power converter according to a first embodiment. The power converter 300 includes a load R, a high-side PMOSFET coupled between the load and a voltage supply, and a low-side NMOSFET coupled between the load and ground. In this first embodiment, the PMOSFET is a split gate PMOSFET and the NMOSFET is a split gate NMOSFET. In a second embodiment, the PMOSFET is a split gate PMOSFET and the NMOSFET is a single gate NMOSFET, such as the power converter 400 shown in FIG. 5. In a third embodiment, the PMOSFET is a single gate PMOSFET and the NMOSFET is a split-gate NMOSFET, such as the power converter 500 shown in FIG. 6.

The split gate power transistor has been described in terms of specific embodiments incorporating details to facilitate the understanding of the principles of construction and operation of the power transistor. Such references, herein, to specific embodiments and details thereof are not intended to limit the scope of the claims appended hereto. It will be apparent to those skilled in the art that modifications can be made in the embodiments chosen for illustration without departing from the spirit and scope of the power transistor.

1-35. (canceled)

36. An integrated circuit transistor comprising:
a doped P type substrate comprising:
a doped N type buried layer;
a doped N type epitaxial layer adjacent to said doped N type buried layer;
a first doped N type region comprising a second doped N type region;
a doped P type region adjacent to said doped N type epitaxial layer;
a doped P type isolation ring that forms a perimeter around said doped N type epitaxial layer to isolate other circuits from said integrated circuit transistor and said doped N type epitaxial layer;
a first channel region within said second doped N type region located underneath a first gate; and
a second channel region within said first doped N type region and said doped N type epitaxial layer located underneath a second gate.

37. The integrated circuit transistor of claim 36 wherein said second doped N type region is doped at a higher N type concentration than said first doped N type region.

38. The integrated circuit transistor of claim 36 wherein said first doped N type region is doped at a higher N type concentration that said doped N type epitaxial layer.

39. The integrated circuit transistor of claim 36 wherein said second doped N type region comprises:
a doped P+ type bridge region;
a doped N+ type region; and
a first doped P+ type region.

40. The integrated circuit transistor of claim 39 wherein a merged contact is electrically coupled to a surface of said a doped N+ type region, said doped P+ type bridge region, said first channel region, said doped P+ type bridge region, and said second channel region.

41. The integrated circuit transistor of claim 39 wherein an oxide filled trench is located adjacent to said first doped N type region, said second doped N type region, said doped N+ type region, and said doped P type isolation ring.

42. The integrated circuit transistor of claim 39 wherein said doped P type region comprises:
an oxide filled trench; and
a second doped P+ type region.

43. The integrated circuit transistor of claim 42 wherein a source contact terminal is electrically coupled to said merged contact and a drain contact terminal is electrically coupled to said second doped P+ type region.

44. The integrated circuit transistor of claim 36 wherein said doped N type buried layer is doped at a higher N type concentration than said doped N type epitaxial layer.

45. The integrated circuit transistor of claim 40 wherein said doped P type region comprises a transition region located underneath said merged contact.

46. The integrated circuit transistor of claim 42 wherein said doped P type region comprises a drift region located underneath said oxide filled trench.

47. The integrated circuit transistor of claim 36 wherein said first gate and said second gate are electrically isolated from each other.

48. The integrated circuit transistor of claim 36 wherein said first gate is electrically coupled to a constant voltage and said second gate is electrically coupled to a switching voltage.
